(19) United States
(12) Patent Application Publication
(10) Pub. No.: US 2023/0335627 A1
(43) Pub. Date: Oct. 19, 2023

(54) SEMICONDUCTOR DEVICE

(71) Applicant: FUJI ELECTRIC CO., LTD., Kanagawa (JP)

(72) Inventor: Naoki MITAMURA, Matsumoto-city (JP)

(21) Appl. No.: 18/172,350

(22) Filed: Feb. 22, 2023

(30) Foreign Application Priority Data
Apr. 18, 2022 (JP) 2022-068072

(51) Int. Cl. H01L 29/739; H01L 29/40

(52) U.S. Cl. CPC H01L 29/7397; H01L 29/407

(57) ABSTRACT

A semiconductor device includes: a plurality of trench portions provided in a semiconductor substrate; a mesa portion provided between the plurality of trench portions in the semiconductor substrate; and a front surface metal layer provided above the semiconductor substrate, wherein each of the plurality of trench portions has: a gate trench portion including a gate conductive portion and a gate dielectric film; and a dummy trench portion including a dummy conductive portion and a dummy dielectric film, and the front surface metal layer has: an upper region in contact with an upper surface of the mesa portion in direct contact with the dummy trench portion; and an embedded region that is embedded in the semiconductor substrate and is in contact with a side wall of the mesa portion and the dummy conductive portion.

The contents of the following Japanese patent application(s) are incorporated herein by reference:
NO. 2022-068072 filed in JP on Apr. 18, 2022

### BACKGROUND

### 1. Technical Field

The present invention relates to a semiconductor device.

### 2. Related Art

Patent Document 1 describes that, in RC-IGBT, “the goal is to provide a technique that allows effective reduction of recovery loss”. Patent Document 2 describes that, in RC-IGBT and in a semiconductor device provided with a vertical MOS transistor, “a bottom portion of a second trench 10 constituting a dummy gate structure is located deeper than a bottom portion of a first trench 7 constituting a trench gate structure”.

### PRIOR ART DOCUMENTS

### Patent Documents

Patent Document 1: Japanese Patent Application Publication No. 2022-15861
Patent Document 2: Japanese Patent Application Publication No. 2013-84905

### BRIEF DESCRIPTION OF THE DRAWINGS

FIG. 1 shows an example of a top view of a semiconductor device 100 according to an embodiment.

FIG. 2A shows an example of a cross section along a-a′ in FIG. 1.

FIG. 2B shows an example of a cross section along b-b′ in FIG. 1.

FIG. 3 compares the semiconductor device 100 and a semiconductor device 1100 according to a comparative example.

FIG. 4 shows another example of the top view of the semiconductor device 100 according to an embodiment.

FIG. 5 shows an example of a cross section along c-c′ in FIG. 4.

FIG. 6 shows another example of the cross section along a-a′ in FIG. 1.

FIG. 7 shows another example of the cross section along a-a′ in FIG. 1.

FIG. 8 shows an example of a method for manufacturing the semiconductor device 100.

FIG. 9 shows an example of a method for manufacturing the semiconductor device 100.

### DESCRIPTION OF EXEMPLARY EMBODIMENTS

Hereinafter, the present invention will be described through embodiments of the invention, but the following embodiments do not limit the claimed invention. Also, not all combinations of features described in the embodiments are necessary to the solution of the invention.

In this specification, one side in a direction parallel to a depth direction of a semiconductor substrate is referred to as “upper”, and the other side is referred to as “lower”. One surface of two main surfaces of a substrate, a layer, or other members is referred to as an upper surface, and the other surface as a lower surface. The “upper”, “lower”, “front”, and “back” directions are not limited to a gravitational direction or to a direction of attachment to a substrate or the like of a semiconductor device when mounted.

In this specification, technical matters may be described by using orthogonal coordinate axes of an X axis, a Y axis, and a Z axis. In this specification, a plane parallel to a front surface of the semiconductor substrate is defined as an XY plane, and the depth direction of the semiconductor substrate is defined as the Z axis. It should be noted that, in this specification, a view of the semiconductor substrate in a Z axis direction is referred to as a planar view.

Although, for each of the embodiments, an example is shown in which a first conductivity type and a second conductivity type are respectively defined as an N type and a P type, the first conductivity type and the second conductivity type may be respectively defined as the P type and the N type. In this case, conductivity types of respective substrates, layers, regions, and the like in these examples for each of the embodiments are of opposite polarity.

In this specification, the layer and region denoted by a character N or P respectively represent the layer and region where an electron or a hole is a majority carrier. Also, the layer and region denoted by the character N or P added with a symbol “+” or “−” respectively represent the layer and region having doping concentrations higher or lower than those of the layer and region without these symbols. A symbol “++” represents a higher doping concentration than the symbol “+”, while a symbol “−−” represents a lower doping concentration than the symbol “−”.

In this specification, a doping concentration refers to a concentration of a donor or an acceptorized dopant. Therefore, the unit is /cm³. In this specification, a difference between donor and acceptor concentrations (that is, a net doping concentration) may be used as the doping concentration. In this case, the doping concentration can be measured by an SRP method. Also, donor and acceptor chemical concentrations may be used as the doping concentration. In this case, the doping concentration can be measured by an SIMS method. Unless otherwise specified, any of the above concentrations may be used as the doping concentration. Unless otherwise specified, a peak value of a doping concentration distribution in a doping region may be used as the doping concentration in that doping region.

Also, in this specification, a dose amount refers to the number of ions implanted into a wafer per unit area during ion implantation. Therefore, the unit is /cm². It should be noted that a dose amount of a semiconductor region can be defined as an integrated concentration which is obtained by integrating doping concentrations across the semiconductor region in the depth direction. The unit of the integrated concentration is /cm². Therefore, the dose amount and the integrated concentration may be treated as the same. The integrated concentration may be defined as an integrated value up to a half-value width, and in case of overlapping with a spectrum of another semiconductor region, it may be derived by excluding influence of that another semiconductor region.

Accordingly, in this specification, a level of the doping concentration can be interpreted as a level of the dose amount. That is, when the doping concentration of one region is higher than the doping concentration of another region, the dose amount of that one region can be understood as being higher than the dose amount of that another region.

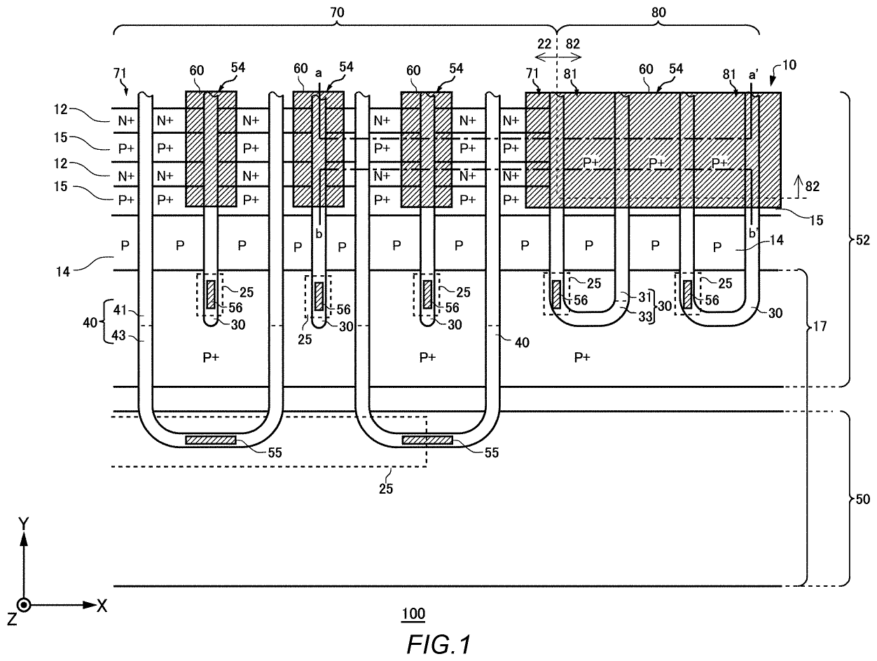

FIG. 1 shows an example of a top view of a semiconductor device 100 according to an embodiment. FIG. 1 shows a position of each member as its projection onto a front surface of a semiconductor substrate 10. FIG. 1 shows only some members of the semiconductor device 100, and omits some members.

The semiconductor device 100 includes the semiconductor substrate 10. Simple reference to a top view in this specification refers to a view of the semiconductor substrate 10 from its front surface side. The semiconductor substrate 10 in this example has two sets of end sides facing each other in the top view. In the figure, an X axis is parallel to an array direction of a plurality of trench portions described below, and a Y axis is parallel to an extending direction of the plurality of trench portions. Also, a Z axis is perpendicular to the front surface of the semiconductor substrate 10.

FIG. 1 shows an active region provided in the semiconductor substrate 10. The active region is where a main current flows in a depth direction between the front surface and a back surface of the semiconductor substrate 10 when the semiconductor device is operated. Although being omitted in FIG. 1, an emitter electrode is provided above the active region.

The active region is provided with: a transistor portion 70 including a transistor element such as an IGBT; and a diode portion 80 including a diode element such as a free wheel diode (FWD). The semiconductor device 100 in this example is a Reverse Conducting IGBT (RC-IGBT).

In the example of FIG. 1, transistor portions 70 and diode portions 80 are alternately arranged along a predetermined array direction (an X axis direction in this example) in the front surface of the semiconductor substrate 10. In another example, the semiconductor device 100 may be an IGBT in which the active region is provided with only the transistor portions 70.

In this specification, a direction perpendicular to the array direction in the top view may be referred to as an extending direction (a Y axis direction in FIG. 1). The transistor portion 70 and the diode portion 80 may each have a longitudinal length in the extending direction. That is, a length of the transistor portion 70 in the Y axis direction is larger than its width in the X axis direction. Similarly, a length of the diode portion 80 in the Y axis direction is larger than its width in the X axis direction. The extending direction of the transistor portion 70 and the diode portion 80, and a longitudinal direction of each of the trench portions described below may be the same.

The diode portion 80 has a cathode region of an N+ type in a region in contact with the back surface of the semiconductor substrate 10. In this specification, a region provided with the cathode region is referred to as the diode portion 80. That is, the diode portion 80 is a region overlapping with the cathode region in the top view. The back surface of the semiconductor substrate 10 may be provided with a collector region of a P+ type in a region other than the cathode region.

The transistor portion 70 includes the collector region of the P+ type in the region in contact with the back surface of the semiconductor substrate 10. Also, the transistor portion 70 includes an emitter region 12 of an N type, a base region 14 of a P type, and a gate trench portion 40 having a gate conductive portion and a gate dielectric film which are periodically arranged on the front surface side of the semiconductor substrate 10.

The semiconductor device 100 may have one or more pads above the semiconductor substrate 10. By way of example, the semiconductor device 100 may have pads such as a gate pad, an anode pad, a cathode pad, and a current detection pad. Each of the pads is arranged in an edge termination structure portion enclosing the active region in the top view. When the semiconductor device 100 is mounted, each of the pads may be connected to an external circuit via a wiring line such as a wire.

A gate metal layer 50 is arranged in the edge termination structure portion. The gate metal layer 50 connects the gate trench portion and the gate pad. The gate metal layer 50 in this example encloses the active region in the top view. A region enclosed by the gate metal layer 50 in the top view may be defined as the active region.

The edge termination structure portion is arranged between the gate metal layer 50 and the end sides of the semiconductor substrate 10. The edge termination structure portion reduces electric field strength on the front surface side of the semiconductor substrate 10. The edge termination structure portion may have a plurality of guard rings. The guard ring is a region of the P type in contact with the front surface of the semiconductor substrate 10. Providing the plurality of guard rings allows outward extension of a depletion layer on an upper surface side of the active region, and allows improvement of a breakdown voltage of the semiconductor device 100. The edge termination structure portion may further include at least one of a field plate or a RESURF annularly provided enclosing the active region.

The transistor portion 70 is a region as a projection of a collector region 22 provided on the back surface side of the semiconductor substrate 10 onto the front surface of the semiconductor substrate 10. The collector region 22 in this example is of the P+ type by way of example. The transistor portion 70 includes a transistor such as an IGBT.

The diode portion 80 is a region as a projection of a cathode region 82 provided on the back surface side of the semiconductor substrate 10 onto the front surface of the semiconductor substrate 10. The cathode region 82 in this example is of the N+ type by way of example. The diode portion 80 includes a diode such as a free wheel diode (FWD) provided in direct contact with the transistor portion 70 in the front surface of the semiconductor substrate 10.

The semiconductor substrate 10 may be a silicon substrate, may be a silicon carbide substrate, or may be a nitride semiconductor substrate or the like such as gallium nitride. The semiconductor substrate 10 in this example is a silicon substrate.

The semiconductor device 100 in this example includes the gate trench portion 40, a dummy trench portion 30, an emitter region 12, a base region 14, a contact region 15, and a well region 17, in the front surface of the semiconductor substrate 10. Also, the semiconductor device 100 in this example includes an emitter electrode 52 and the gate metal layer 50 which are provided above the front surface of the semiconductor substrate 10.

The emitter electrode 52 is provided above the gate trench portion 40, the dummy trench portion 30, the emitter region 12, the base region 14, the contact region 15, and the well region 17. Also, the gate metal layer 50 is provided above the gate trench portion 40 and the well region 17.

The emitter electrode 52 and the gate metal layer 50 are formed of a material including metal. At least some regions of the emitter electrode 52 may be formed of aluminum, an aluminum-silicon alloy, or an aluminum-silicon-copper alloy. At least some regions of the gate metal layer 50 may be formed of aluminum, an aluminum-silicon alloy, or an aluminum-silicon-copper alloy. The emitter electrode 52 and the gate metal layer 50 may have a barrier metal formed of titanium, titanium compound, or the like, which underlies the regions formed of aluminum or the like. The emitter electrode 52 and the gate metal layer 50 are provided separately from each other.

The emitter electrode 52 and the gate metal layer 50 are provided above the semiconductor substrate 10 with an interlayer dielectric film 38 interposed therebetween. The interlayer dielectric film 38 is omitted in FIG. 1. The interlayer dielectric film 38 is provided with a contact hole 54, a contact hole 55, and a contact hole 56 which run therethrough.

The contact hole 55 connects the gate conductive portion in the gate trench portion 40 of the transistor portion 70, and the gate metal layer 50. A plug may be formed in the contact hole 55, which plug is formed of tungsten or the like.

The contact hole 56 connects dummy conductive portions in the dummy trench portions 30 which are provided in the transistor portion 70 and the diode portion 80, and the emitter electrode 52. A plug may be formed in the contact hole 56, which plug is formed of tungsten or the like.

A connecting portion 25 electrically connects a front surface side electrode such as the emitter electrode 52 or the gate metal layer 50, and the semiconductor substrate 10. In an example, the connecting portion 25 is provided in a region that is between the gate metal layer 50 and the gate conductive portion and that includes an interior of the contact hole 55. The connecting portion 25 may also be provided in a region that is between the emitter electrode 52 and the dummy conductive portion and that includes an interior of the contact hole 56. The connecting portion 25 is formed of a conductive material, for example, metal such as tungsten or polysilicon doped with an impurity. Also, the connecting portion 25 may have a barrier metal formed of titanium nitride or the like. Here, the connecting portion 25 is formed of polysilicon (N+) doped with an impurity of the N type. The connecting portion 25 is provided above the front surface of the semiconductor substrate 10 via, for example, a dielectric film such as an oxide film.

Gate trench portions 40 are arrayed at a predetermined interval along a predetermined array direction (the X axis direction in this example). The gate trench portion 40 in this example may have: two extending portions 41 extending along the extending direction (the Y axis direction in this example) that is parallel to the front surface of the semiconductor substrate 10 and that is perpendicular to the array direction; and a connecting portion 43 connecting the two extending portions 41.

Preferably, at least a part of the connecting portion 43 is formed into a curve. Connecting end portions of the two extending portions 41 of the gate trench portion 40 allows reduction of electric field strength at the end portions of the extending portions 41. At the connecting portion 43 of the gate trench portion 40, the gate metal layer 50 may be connected to the gate conductive portion.

The dummy trench portion 30 is a trench portion the dummy conductive portion provided therein is electrically connected to the emitter electrode 52. Similarly to the gate trench portions 40, the dummy trench portions 30 are arrayed at a predetermined interval along a predetermined array direction (the X axis direction in this example). Similarly to the gate trench portion 40, the dummy trench portion 30 in this example may be in a U-shape in the front surface of the semiconductor substrate 10. That is, the dummy trench portion 30 may have: two extending portions 31 extending along the extending direction; and a connecting portion 33 connecting the two extending portions 31.

The transistor portion 70 in this example has a structure in which the gate trench portions 40 and the dummy trench portions 30 are alternately arrayed. That is, the transistor portion 70 in this example has the gate trench portions 40 and the dummy trench portions 30 at a ratio of 1:1. For example, the transistor portion 70 has one extending portion 31 between the two extending portions 41.

However, the ratio of the gate trench portions 40 and the dummy trench portions 30 is not limited to this example. The ratio of the gate trench portions 40 and the dummy trench portions 30 may be 1:2, or may be 2:3. Also, the transistor portion 70 may have a so-called full gate structure in which it is not provided with any dummy trench portion 30 but with only the gate trench portions 40.

The well region 17 is provided on the front surface side of the semiconductor substrate 10 with respect to a drift region 18 described below. The well region 17 is an example of a well region provided on an edge side of the semiconductor device 100. The well region 17 is of the P+ type by way of example. The well region 17 is formed in a predetermined range from an end portion of the active region on a side where the gate metal layer 50 is provided. The well region 17 may have a diffusion depth larger than depths of the gate trench portion 40 and the dummy trench portion 30. Some regions of the gate trench portion 40 and the dummy trench portion 30 on the gate metal layer 50 side are formed in the well region 17. Bottoms of the gate trench portion 40 and the dummy trench portion 30 at their ends in the extending direction may be covered with the well region 17.

The contact hole 54 is provided above the dummy trench portion 30. No contact hole 54 is provided above the well region 17 provided at the both ends in the Y axis direction. Thus, one or more contact holes 54 are formed in the interlayer dielectric film. The one or more contact holes 54 may be provided extending in the extending direction.

A front surface metal layer in this example further has an upper region 60. The upper region 60 electrically connects the emitter electrode 52 and the semiconductor substrate 10, and constitutes the front surface metal layer together with the emitter electrode 52. The upper region 60 is provided in the contact hole 54. The upper region 60 is provided extending in the extending direction. That is, the upper region 60 is arranged in stripes along the gate trench portion 40 and the dummy trench portion 30.

A mesa portion 71 and a mesa portion 81 are provided in direct contact with the trench portion, in a plane parallel to the front surface of the semiconductor substrate 10. The mesa portion may be a portion that is sandwiched between two adjacent trench portions and that is of the semiconductor substrate 10, and may range from the front surface of the semiconductor substrate 10 to a depth of a bottom portion of each of the trench portions corresponding to the deepest level of that trench portion. An extending portion of each of the trench portions may be defined as one trench portion. That is, a region sandwiched between two extending portions may be defined as a mesa portion.

A mesa portion 71 is provided in direct contact with at least one of the dummy trench portion 30 or the gate trench portion 40, in the transistor portion 70. The mesa portion 71 has the well region 17, the emitter region 12, the base region 14, and the contact region 15, in the front surface of the semiconductor substrate 10.

The mesa portion 81 is provided in a region sandwiched between the dummy trench portions 30 adjacent to each other, in the diode portion 80. In the front surface of the semiconductor substrate 10, the mesa portion 81 in this example has the base region 14, and has the well region 17 on a negative side in the Y axis direction.

The base region 14 is provided on the front surface side of the semiconductor substrate 10, in the transistor portion 70 and the diode portion 80. The base region 14 is of the P type by way of example. The base region 14 may be provided at both end portions of the mesa portion 71 and the mesa portion 81 in the Y axis direction, in the front surface of the semiconductor substrate 10. It should be noted that FIG. 1 shows only an end portion of that base region 14 on the negative side in the Y axis direction.

The emitter region 12 is of the same conductivity type as that of the drift region 18, and has a doping concentration higher than that of the drift region 18. The emitter region 12 in this example is of the N+ type by way of example. A dopant of the emitter region 12 is exemplified as arsenic (As). The emitter region 12 is provided in contact with the gate trench portions 40, in an upper surface of the mesa portion 71. The emitter region 12 may be provided extending in the X axis direction, from one to the other of the two trench portions sandwiching the mesa portion 71. The emitter region 12 is also provided below the contact hole 54.

Also, the emitter region 12 may or may not be in contact with the dummy trench portion 30. The emitter region 12 in this example is in contact with the dummy trench portion 30. The emitter region 12 may not be provided in the mesa portion 81.

The contact region 15 is of the same conductivity type as that of the base region 14, and has a doping concentration higher than that of the base region 14. The contact region 15 in this example is of the P+ type by way of example. The contact region 15 in this example is provided in the upper surface of the mesa portion 71.

The contact region 15 may be provided in the X axis direction, from one to the other of the two trench portions sandwiching the mesa portion 71. The contact region 15 may or may not be in contact with the gate trench portion 40. Also, the contact region 15 may or may not be in contact with the dummy trench portion 30. In this example, the contact region 15 is in contact with the dummy trench portion 30 and the gate trench portion 40.

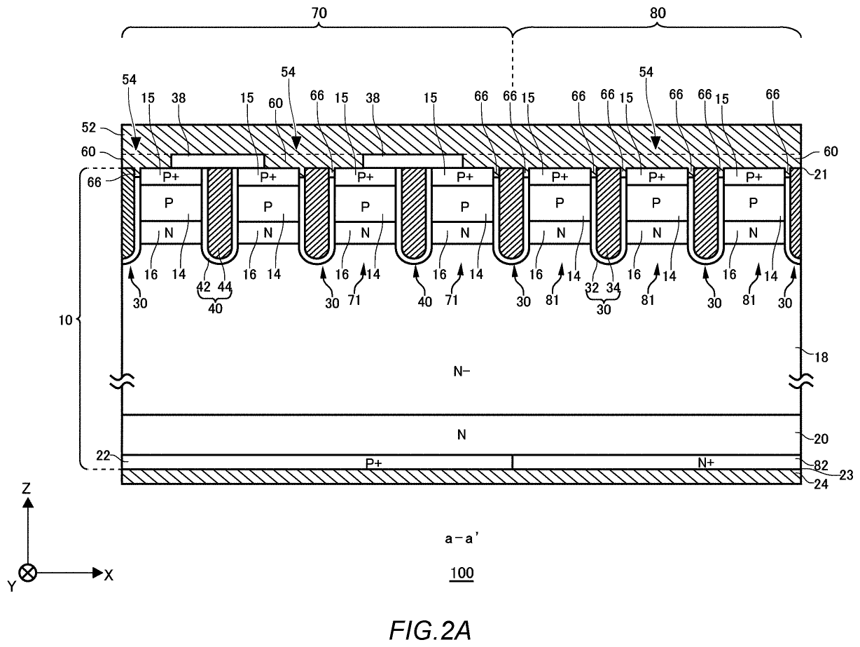

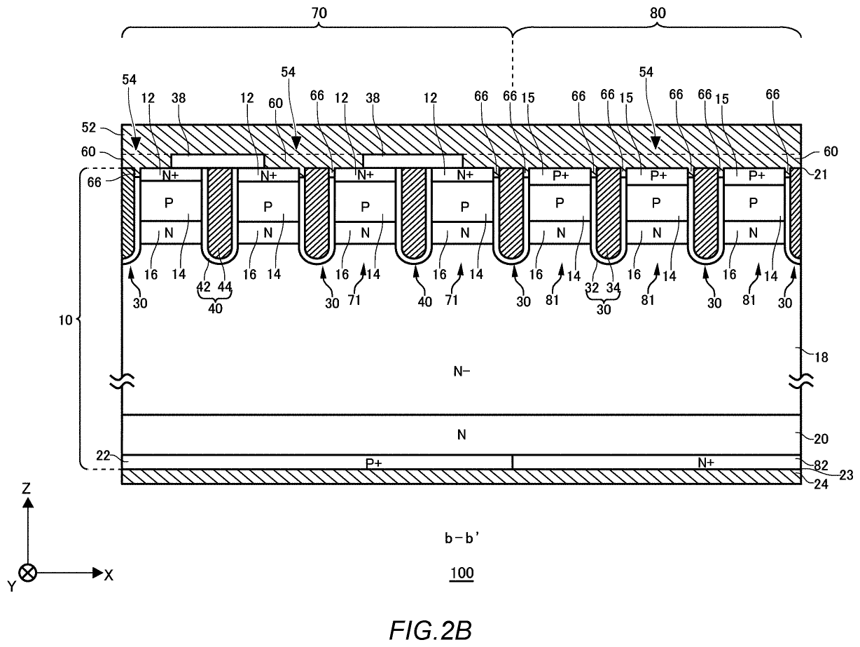

FIG. 2A shows an example of a cross section along a-a′ in FIG. 1. FIG. 2B shows an example of a cross section along b-b′ in FIG. 1. The cross section along a-a′ in FIG. 2A is an XZ plane passing through the contact region 15 in the transistor portion 70. The cross section along b-b′ in FIG. 2B is an XZ plane passing through the emitter region 12 in the transistor portion 70. It should be noted that, in the following examples, the XZ plane passing through the contact region 15 is shown as a representative cross section, and the XZ plane passing through the emitter region 12 is omitted. The XZ plane passing through the emitter region 12 is in common with the XZ plane passing through the contact region 15 according to the same example, except that the emitter region 12 is replaced with the contact region 15.

The semiconductor device 100 in this example has the semiconductor substrate 10, the interlayer dielectric film 38, the emitter electrode 52, the upper region 60, an embedded region 66, and a collector electrode 24, in the cross section along a-a′ and the cross section along b-b′. The upper region 60 and the interlayer dielectric film 38 are formed above the semiconductor substrate 10, and the emitter electrode 52 is formed above the upper region 60 and the interlayer dielectric film 38.

The drift region 18 is provided in the semiconductor substrate 10. The drift region 18 in this example is of an N− type by way of example. The drift region 18 may be a region left in the semiconductor substrate 10 without other doping regions formed. That is, a doping concentration of the drift region 18 may be a doping concentration of the semiconductor substrate 10.

The buffer region 20 is provided below the drift region 18. The buffer region 20 in this example is of the same conductivity type as that of the drift region 18, and is of the N type by way of example. A doping concentration of the buffer region 20 is higher than the doping concentration of the drift region 18. The buffer region 20 may serve as a field stop layer that prevents a depletion layer expanding from a lower surface side of the base region 14 from reaching the collector region 22 and the cathode region 82.

The collector region 22 is provided below the buffer region 20 in the transistor portion 70, and is of a conductivity type different from that of the drift region 18. The cathode region 82 is provided below the buffer region 20 in the diode portion 80, and is of the same conductivity type as that of the drift region 18. A boundary between the collector region 22 and the cathode region 82 is a boundary between the transistor portion 70 and the diode portion 80.

The collector electrode 24 is formed on a back surface 23 of the semiconductor substrate 10. The collector electrode 24 is formed of a conductive material such as metal.

The base region 14 is provided above the drift region 18 in the mesa portion 71 and the mesa portion 81, and is of a conductivity type different from that of the drift region 18. The base region 14 in this example is the P type by way of example. The base region 14 is provided in contact with gate trench portion 40. The base region 14 may be provided in contact with the dummy trench portion 30. A thickness of the base region 14, that is, a distance from an upper surface to a lower surface of the base region 14 in a Z axis direction is 1 to 2 μm.

The emitter region 12 is provided between the base region 14 and a front surface 21. The emitter region 12 in this example is provided in the mesa portion 71, and is not provided in the mesa portion 81. The emitter region 12 is provided in contact with the gate trench portion 40. The emitter region 12 may or may not be in contact with the dummy trench portion 30. The emitter region 12 may be provided shallower than the contact region 15.

The contact region 15 is provided above the base region 14, in the mesa portion 71 and the mesa portion 81. The contact region 15 is provided in contact with the dummy trench portion 30, in the mesa portion 71 and the mesa portion 81. The contact region 15 is provided in the upper surface of the mesa portion 71. A thickness of the contact region 15, that is, a distance from an upper surface of the mesa portion to a lower surface of the contact region 15 in the Z axis direction is 0.1 to 0.3 μm.

An accumulation region 16 is provided on the front surface 21 side of the semiconductor substrate 10 with respect to the drift region 18. The accumulation region 16 in this example is of the same conductivity type as that of the drift region 18, and is of the N+ type by way of example. The accumulation region 16 is provided in the transistor portion 70 and the diode portion 80. However, the accumulation region 16 may not be provided.

Also, the accumulation region 16 is provided in contact with the gate trench portion 40. The accumulation region 16 may or may not be in contact with the dummy trench portion 30. A doping concentration of the accumulation region 16 is higher than the doping concentration of the drift region 18. Providing the accumulation region 16 allows enhancement of a carrier injection enhancement effect (IE effect) and reduction of an ON voltage of the transistor portion 70.

One or more gate trench portions 40 and one or more dummy trench portions 30 are provided in the front surface 21 of the semiconductor substrate 10. Each of the trench portions is provided from the front surface 21 of the semiconductor substrate 10 to the drift region 18. In a region where at least one of the emitter region 12, the base region 14, the contact region 15, or the accumulation region 16 is provided, each of the trench portions also runs through these regions to reach the drift region 18. A configuration of the trench portion running through the doping region is not limited to what is manufactured in the order of forming a doping region and then forming trench portions. The configuration of the trench portion running through the doping region also includes what is manufactured in the order of forming trench portions and then forming a doping region between the trench portions.

The gate trench portion 40 has a gate trench, a gate dielectric film 42, and a gate conductive portion 44 that are formed in the front surface 21 of the semiconductor substrate 10. The gate dielectric film 42 is provided covering an inner wall of the gate trench. The gate dielectric film 42 may be formed by oxidizing or nitriding a semiconductor on the inner wall of the gate trench. The gate conductive portion 44 is provided farther inward in the gate trench than the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 on the front surface 21 of the semiconductor substrate 10.

In the depth direction of the semiconductor substrate 10, the gate conductive portion 44 includes a region facing the base region 14 that is adjacent to the gate conductive portion 44 on the mesa portion 71 side with the gate dielectric film 42 interposed therebetween. When a predetermined voltage is applied to the gate conductive portion 44, a channel is formed by an electron inversion layer in a surface layer of a boundary surface that is of the base region 14 and that is in contact with the gate trench.

The dummy trench portion 30 may have the same structure as that of the gate trench portion 40. The dummy trench portion 30 has a dummy trench, a dummy dielectric film 32, and a dummy conductive portion 34 formed on the front surface 21 side of the semiconductor substrate 10. The dummy dielectric film 32 is provided covering an inner wall of the dummy trench. The dummy conductive portion 34 is provided in the dummy trench, and is provided farther inward than the dummy dielectric film 32. The dummy dielectric film 32 insulates the dummy conductive portion 34 from the semiconductor substrate 10. The dummy trench portion 30 is covered by the interlayer dielectric film 38 on the front surface 21 of the semiconductor substrate 10.

The interlayer dielectric film 38 is provided on the front surface 21 of the semiconductor substrate 10. The emitter electrode 52 is provided above the interlayer dielectric film 38. The interlayer dielectric film 38 is provided with one or more contact holes 54 for electrically connecting the emitter electrode 52 and the semiconductor substrate 10. Similarly, the contact hole 55 and the contact hole 56 may be provided running through the interlayer dielectric film 38.

The upper region 60 has a conductive material filled in the contact hole 54. The upper region 60 is provided above the dummy trench portion 30. The upper region 60 may be provided above the interlayer dielectric film 38. The upper region 60 in this example is provided in contact with the upper surface of the mesa portion in direct contact with the dummy trench portion 30. The upper region 60 may have a plug containing tungsten and a barrier metal containing titanium.

The upper region 60 has a substantially planar bottom surface. Side walls of the upper region 60 may be provided substantially perpendicular to the front surface 21. The upper region 60 in this example is provided in contact with the embedded region 66 embedded in the semiconductor substrate 10.

The embedded region 66 is embedded in the semiconductor substrate 10, and is provided in contact with a side wall of the mesa portion and the dummy conductive portion 34. The embedded region 66 is provided in contact with the dummy dielectric film 32, the side wall of the mesa portion, and the dummy conductive portion 34, above an upper end of the dummy dielectric film 32. The embedded region 66 has a plug containing tungsten and a barrier metal containing titanium. The embedded region 66 is electrically connected to the emitter electrode 52 and the upper region 60, and constitutes the front surface metal layer together with these components.

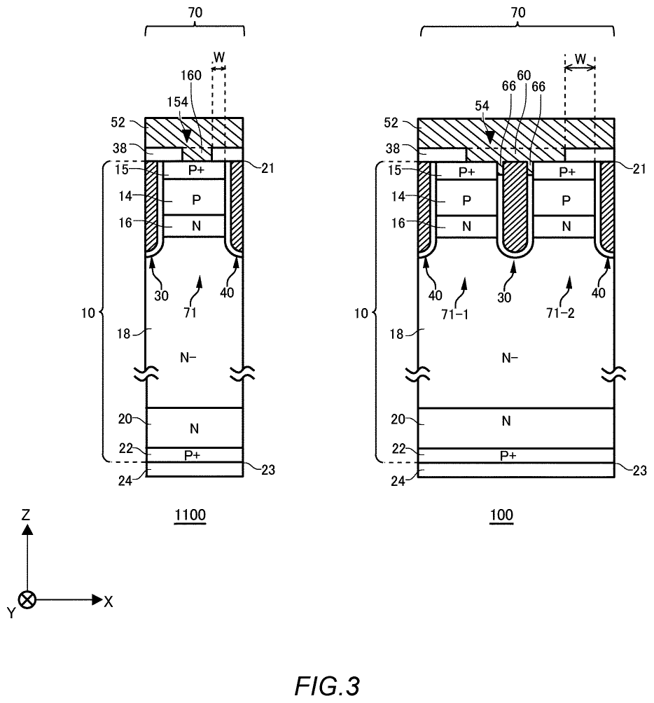

FIG. 3 compares the semiconductor device 100 and a semiconductor device 1100 according to a comparative example. Left and right sides of FIG. 3 respectively show a semiconductor device 1100 according to a comparative example and the semiconductor device 100, both of which are XZ planes passing through the mesa portion 71 between the dummy trench portion 30 and the gate trench portion 40. In the semiconductor device 1100, elements in common with those of the semiconductor device 100 are denoted by the same reference numerals, and description thereof is omitted.

In the semiconductor device 1100 according to the comparative example, an upper region 160 having a conductive material filled in a contact hole 154 is provided on the mesa portion 71 between the dummy trench portion 30 and the gate trench portion 40 that are adjacent to each other. Side walls of the upper region 160 in the X axis direction are both located on the same mesa portion 71. In an example, a width (that is, a distance between the side walls) of the upper region 160 in the X axis direction is approximately 0.5 μm, and a width of the mesa portion 71 is approximately 0.8 μm.

Here, the contact hole 154 is formed by etching the interlayer dielectric film 38. This formation process may generate pattern variation in the order of 0.2 μm. An allowable deviation width W is a distance from a target position of a side wall of the contact hole 154 to a side wall of the mesa portion 71 (that is, a side wall of the dummy trench portion 30 or the gate trench portion 40 that is in direct contact with the mesa portion 71) in the X axis direction.

On the other hand, in the semiconductor device 100, the upper region 60 having a conductive material filled in the contact hole 54 is provided extending across the dummy trench portion 30 in the X axis direction. A first mesa portion 71-1 and a second mesa portion 71-2 in direct contact with the dummy trench portion 30 are examples of the mesa portion 71. In the X axis direction, one side wall of the side walls of the upper region 60 is located on the first mesa portion 71-1 in direct contact with the dummy trench portion 30, and the other side wall is located on the second mesa portion 71-2 in direct contact with the dummy trench portion 30 on a side opposite to the first mesa portion 71-1. In an example, a width of the upper region 60 in the X axis direction is approximately 0.5 μm, and the width of the mesa portion 71 (the first mesa portion 71-1 and the second mesa portion 71-2) is approximately 0.8 μm.

Similarly to the contact hole 154, an allowable deviation width W of the contact hole 54 is a distance from a target position of an end portion of the contact hole 54 to a side wall of the mesa portion 71 (that is, a side wall of the dummy trench portion 30 or the gate trench portion 40 that is in direct contact with the mesa portion 71). However, since the upper region 60 extends across the dummy trench portion 30 in the X axis direction, the allowable deviation width W for the upper region 60 is larger than the allowable deviation width W for the upper region 160 that is entirely arranged only on the same mesa portion 71. In an example, the allowable deviation width W of the contact hole 54 is approximately 50% of the width of the mesa portion 71.

Thus, in the semiconductor device 100, the large allowable deviation width W of the contact hole 54 facilitates alignment even if a pitch of the mesa portion 71 is reduced due to miniaturization of the process, thereby allowing realization of increased density of a device.

Also, since the upper region 60 is provided above the dummy trench portion 30, and is electrically connected to the emitter electrode 52, there is no need to provide a contact between the dummy trench portion 30 and the emitter electrode 52 in the edge termination region. That is, there is no need to provide the contact hole 56 in FIG. 1, or the connecting portion 25 in the contact hole 56. This simplifies a configuration of the edge termination region, and can reduce an area of the edge termination region and seek to reduce a chip size.

A lower end of the embedded region 66 is shallower than a lower end of the base region 14. A distance from an upper end to the lower end of the embedded region 66 is 50% or less of a distance from the front surface 21 of the semiconductor substrate 10 to the lower end of the base region 14. Providing the embedded region 66 in this way can decrease resistance to reduce loss during conduction while preventing reach of a depletion layer.

The lower end of the embedded region may be shallower than a lower end of the contact region 15. Since a forward voltage Vf is reduced when the distance from the upper end to the lower end of the embedded region 66 is small, a current can flow with a small voltage.

Alternatively, the lower end of the embedded region 66 may be deeper than the lower end of the contact region 15. A contact area with the contact region 15 is increased when the distance from the upper end to the lower end of the embedded region 66 is large, which facilitates extraction of a minority carrier (for example, a hole). This improves latch-up resistance due to the minority carrier.

Thus, the contact region 15 provided in the mesa portion in direct contact with the dummy trench portion 30 is in contact with the front surface metal layer on the upper surface and the side wall of the mesa portion. This increases a contact area between the front surface metal layer and the contact region 15 and facilitates the extraction of the minority carrier, thereby improving the latch-up resistance.

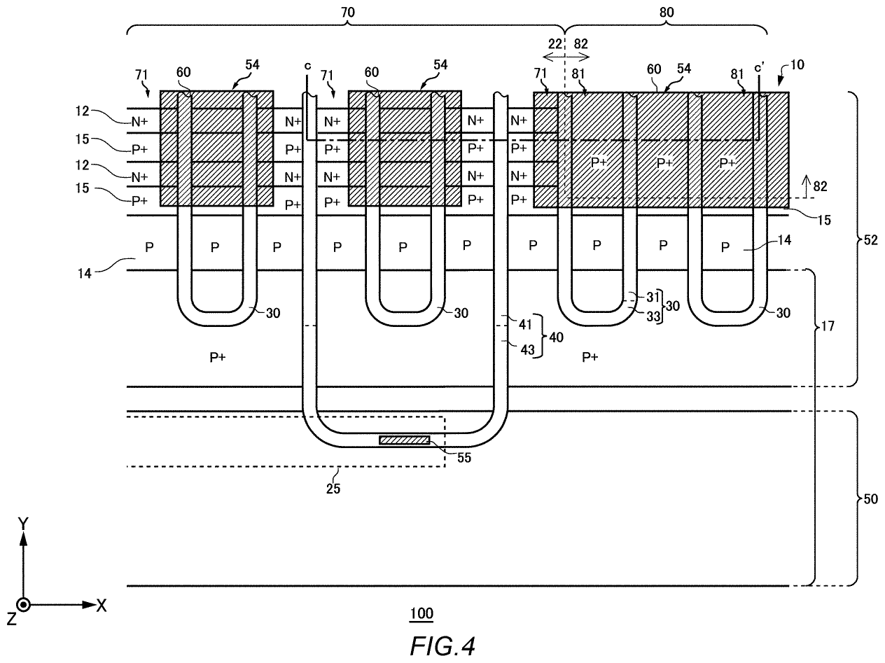

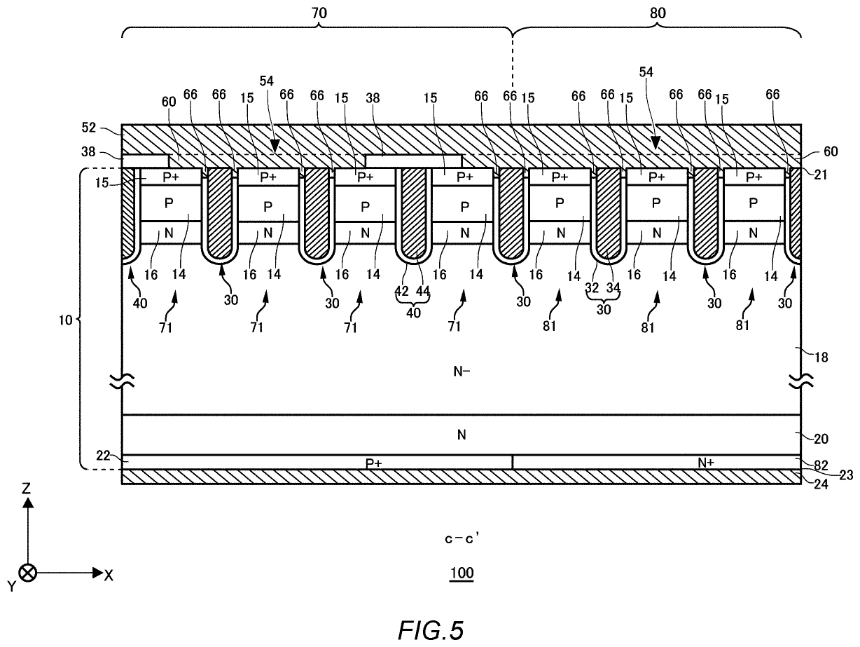

FIG. 4 shows another example of the top view of the semiconductor device 100 according to an embodiment. FIG. 5 shows an example of a cross section along c-c′ in FIG. 4. In the semiconductor device 100 shown in FIG. 4 and FIG. 5, arrangement of dummy trench portions 30 and gate trench portions 40 in a transistor portion 70 is different from that shown in FIG. 1. Also, the semiconductor device 100 shown in FIG. 4 and FIG. 5 is different from the semiconductor device 100 shown in FIG. 1 in that a dummy trench portion 30 is not provided with a contact hole 56 or a connecting portion 25 in the contact hole 56.

The transistor portion 70 in this example has a structure in which two gate trench portions 40 and four dummy trench portions 30 are repeatedly arrayed. That is, the transistor portion 70 in this example has the gate trench portions 40 and the dummy trench portions 30 at a ratio of 1:2. For example, the transistor portion 70 has two extending portions 31 between two extending portions 41.

An upper region 60 is provided extending across a plurality of dummy trench portions 30 in an X axis direction. That is, in the transistor portion 70, the upper region 60 is provided extending across two adjacent dummy trench portions 30.

Thus, when the plurality of dummy trench portions 30 are adjacently provided, even if the upper region 60 is provided extending across the plurality of dummy trench portions 30, it is possible to achieve an effect similar to the one in the example shown in FIG. 1.

It should be noted that, in a diode portion 80, the upper region 60 is provided extending from a dummy trench portion 30 of the plurality of dummy trench portions 30 that is adjacent to a gate trench portion 40 to a dummy trench portion 30 on an opposite side, in the X axis direction. That is, since the diode portion 80 is not provided with any gate trench portion 40 and is provided with only dummy trench portions 30, the upper region 60 may be provided extending across all the dummy trench portions 30 in the X axis direction.

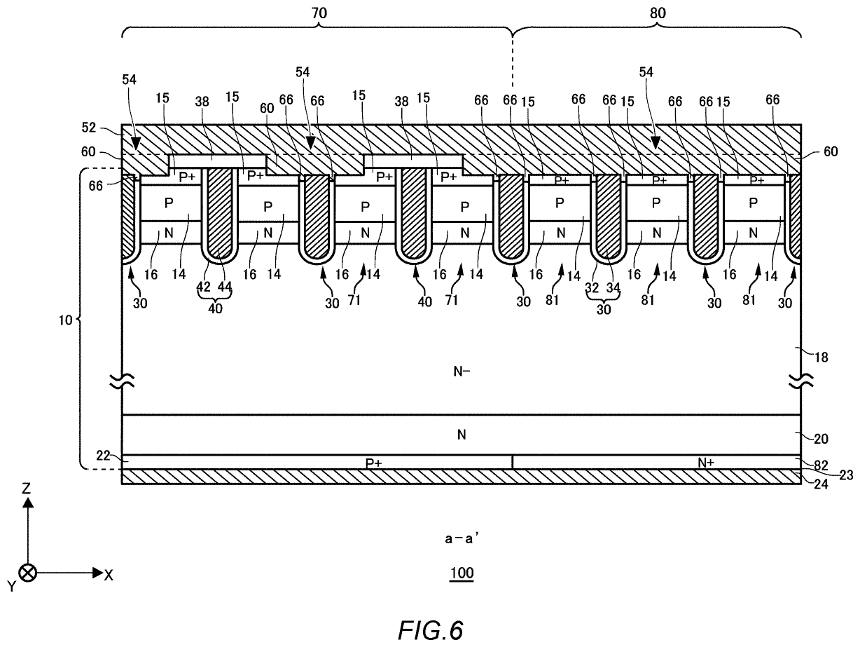

FIG. 6 shows another example of the cross section along a-a′ in FIG. 1. In the semiconductor device 100 shown in FIG. 6, a position of a lower end of an upper region 60 shown in the cross section along a-a′ is different from that shown in the cross section along a-a′ in FIG. 2A.

The lower end of the upper region 60 in this example is provided below a front surface 21 of the semiconductor substrate 10. That is, in this example, a bottom surface of a contact hole 54 is provided below the front surface 21 of the semiconductor substrate 10. The lower end of the upper region 60 may be shallower than a lower end of a contact region 15.

Providing the upper region 60 in this way reduces resistance of a base region 14 and facilitates extraction of a minority carrier, thereby allowing improvement of a destructive breakdown withstand capability such as latch-up resistance. It should be noted that a bottom surface of the upper region 60 may be flat, or may be recessed downward near a center of a dummy trench portion 30 in a width direction (the X axis direction).

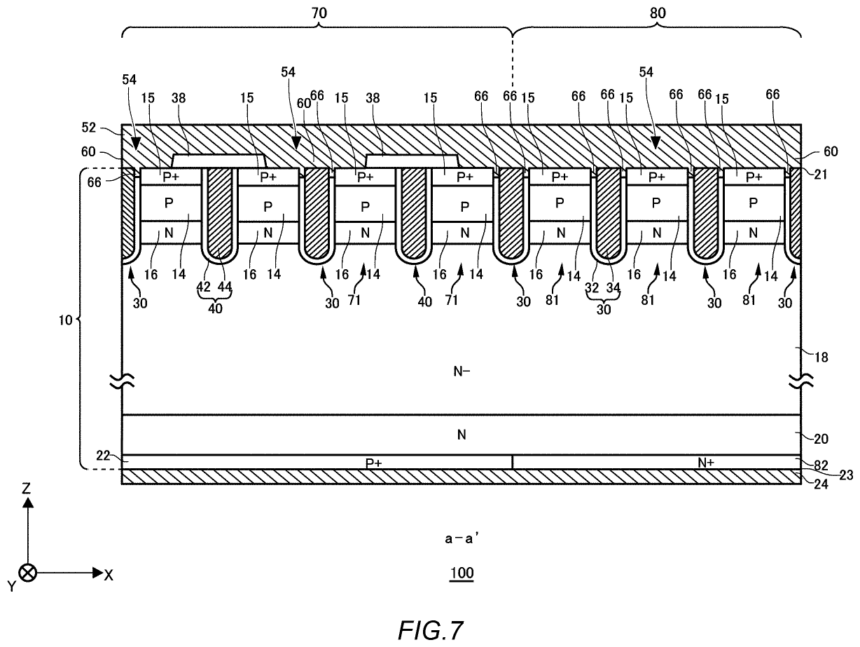

FIG. 7 shows another example of the cross section along a-a′ in FIG. 1. The semiconductor device 100 shown in FIG. 7 has an upper region 60 of which material and cross-sectional shape are different from those of the example described above.

Each of an emitter electrode 52 and an upper region 60 in this example has a conductive material containing aluminum, and an embedded region 66 has a plug containing tungsten and a barrier metal containing titanium. In an example, the emitter electrode 52 and the upper region 60 are formed of an aluminum-silicon alloy. That is, since the emitter electrode 52 and the upper region 60 can be formed of the same material, they can be formed in the same process.

The upper region 60 in this example has a tapered shape with inclined side walls. That is, in this example, an upper surface of a contact hole 54 is provided larger than a bottom surface. This allows the contact hole 54 to be filled with an aluminum-silicon alloy having an embeddability lower than that of tungsten to form the upper region 60.

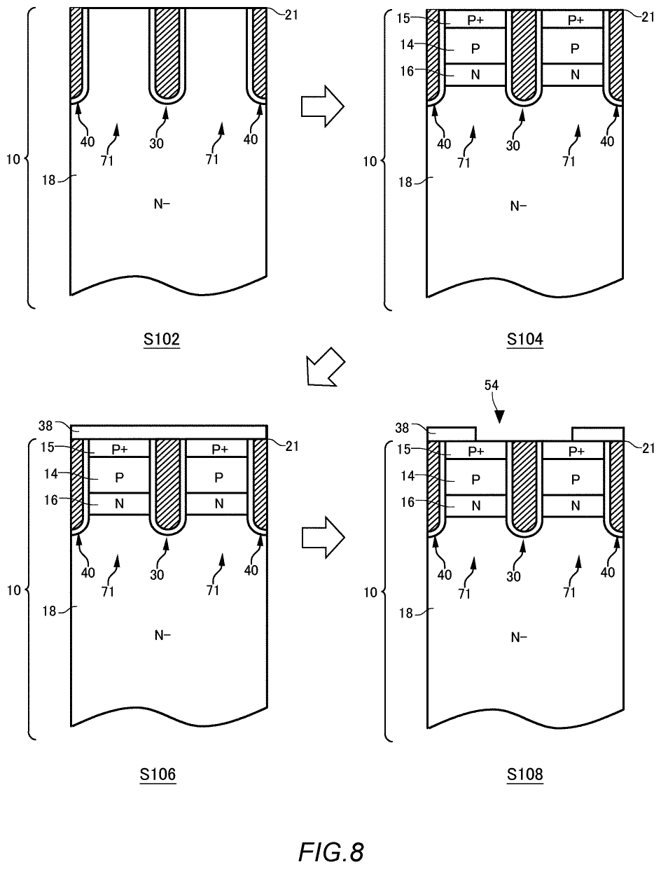

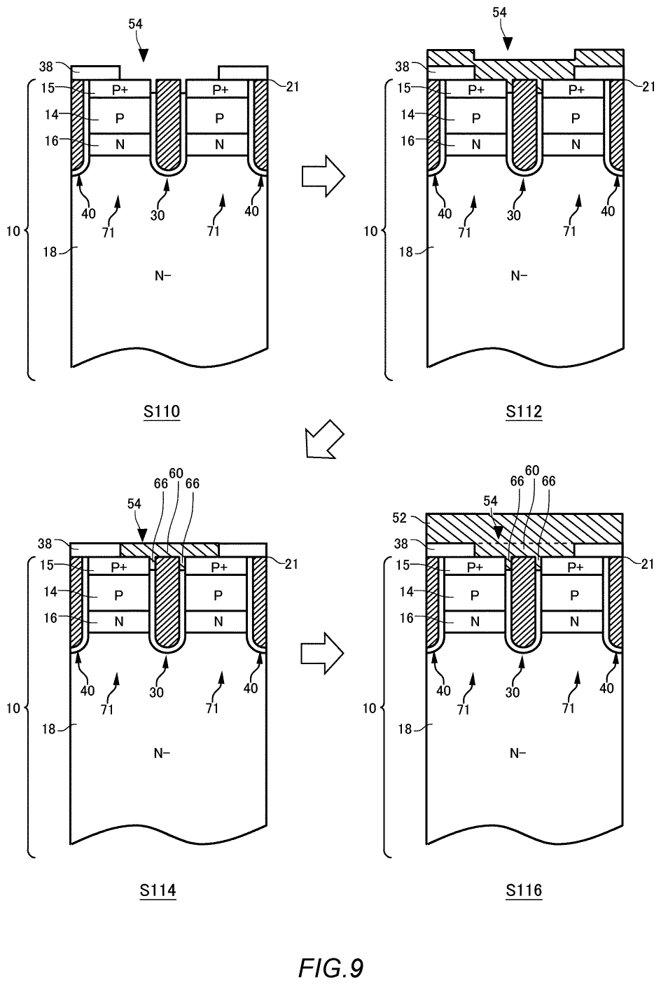

FIG. 8 and FIG. 9 show an example of a method for manufacturing the semiconductor device 100. Here, a process to form a front surface metal layer is mainly described.

In Step S102, a plurality of trench portions are formed. In an example, a trench is formed by etching the semiconductor substrate 10 using a resist mask, and then an inner wall of the trench is oxidized to form an oxide film, and polysilicon is deposited by a CVD method. As a result, a dummy trench portion 30 having a dummy dielectric film 32 and a dummy conductive portion 34 (or a gate trench portion 40 having a gate dielectric film 42 and a gate conductive portion 44) is formed.

In Step S104, doping regions such as an emitter region 12, a base region 14, a contact region 15, and an accumulation region 16 are formed on a front surface 21 side of the semiconductor substrate 10 by doping the semiconductor substrate 10 with an impurity.

In Step S106, an interlayer dielectric film 38 is formed above the front surface 21 of the semiconductor substrate 10. In an example, an oxide film containing a Boro Phospho Silicate Glass (BPSG) is formed by the CVD method on the front surface 21 of the semiconductor substrate 10. In an example, a thickness of the interlayer dielectric film 38 in a Z axis direction is 500 μm or less.

In Step S108, a contact hole 54 is formed by etching the interlayer dielectric film 38 using a resist mask. It should be noted that contact holes 55 and 56 may be formed by a similar procedure.

In Step S110, an upper end of the dummy dielectric film 32 is etched between a side wall of a mesa portion 71 and the dummy conductive portion 34. An etching depth is 50% or less of a distance from the front surface 21 of the semiconductor substrate 10 to a lower end of the base region 14. Here, any of wet etching or dry etching may be used, but the dry etching may be used when the etching depth is large.

In Step S112, an upper region 60 and an embedded region 66 are formed. In an example, a barrier metal containing titanium is formed by sputtering on side walls of a region etched in Step S110 and the contact hole 54, and then tungsten is deposited by the CVD method.

In Step S114, the tungsten on the interlayer dielectric film 38 is removed by etchback. It should be noted that the tungsten may be left on the interlayer dielectric film 38 by omitting this step.

In Step S116, an emitter electrode 52 is formed on the interlayer dielectric film 38. In an example, the emitter electrode 52 is formed by sputtering an aluminum-silicon alloy on the interlayer dielectric film 38.

While the present invention has been described above using embodiments, a technical scope of the present invention is not limited to a scope described in the above embodiments. It is apparent to persons skilled in the art that varied alteration or improvement can be added to the above embodiments. It is apparent from description of the claims that a form added with such alteration or improvement may also be included in the technical scope of the present invention.

It should be noted that each processing such as the operations, procedures, steps, and stages in the apparatus, system, program, and method shown in the claims, the specification, or the drawings may be realized in any order, unless its execution order is specified as “before”, “prior to”, or the like and unless output from previous processing is used in subsequent processing. Even if description is made, regarding an operation flow in the claims, the specification or the drawings, by using “first”, “next”, or the like as a matter of convenience, it does not necessarily mean that the processing must be performed in this order.

### EXPLANATION OF REFERENCES

10: semiconductor substrate, 12: emitter region, 14: base region, 15: contact region, 16: accumulation region, 17: well region, 18: drift region, 21: front surface, 22: collector region, 23: back surface, 24: collector electrode, 25: connecting portion, 30: dummy trench portion, 31: extending portion, 32: dummy dielectric film, 33: connecting portion, 34: dummy conductive portion, 38: interlayer dielectric film, 40: gate trench portion, 41: extending portion, 42: gate dielectric film, 43: connecting portion, 44: gate conductive portion, 50: gate metal layer, 52: emitter electrode, 54: contact hole, 55: contact hole, 56: contact hole, 60: upper region, 66: embedded region, 70: transistor portion, 71: mesa portion, 80: diode portion, 81: mesa portion, 82: cathode region, 100: semiconductor device, 154: contact hole, 160: upper region, 1100: semiconductor device.

What is claimed is:

1. A semiconductor device comprising:
a plurality of trench portions provided in a semiconductor substrate;
a mesa portion provided between the plurality of trench portions in the semiconductor substrate; and
a front surface metal layer provided above the semiconductor substrate, wherein
the plurality of trench portions include:
a gate trench portion having a gate conductive portion and a gate dielectric film; and
a dummy trench portion having a dummy conductive portion and a dummy dielectric film, and
the front surface metal layer includes:
an upper region that is in contact with an upper surface of the mesa portion in direct contact with the dummy trench portion; and
an embedded region that is embedded in the semiconductor substrate and that is in contact with a side wall of the mesa portion and the dummy conductive portion.

2. The semiconductor device according to claim 1, wherein the embedded region is in contact with the side wall of the mesa portion and the dummy conductive portion above an upper end of the dummy dielectric film.

3. The semiconductor device according to claim 1, further comprising an interlayer dielectric film provided on a front surface of the semiconductor substrate, wherein
the interlayer dielectric film is provided with a contact hole above the dummy trench portion.

4. The semiconductor device according to claim 1, further comprising a base region of a second conductivity type provided in the semiconductor substrate, wherein
a lower end of the embedded region is shallower than a lower end of the base region.

5. The semiconductor device according to claim 4, wherein a distance from an upper end to the lower end of the embedded region is 50% or less of a distance from a front surface of the semiconductor substrate to the lower end of the base region.

6. The semiconductor device according to claim 4, further comprising a contact region of a second conductivity type provided in the front surface of the semiconductor substrate, wherein
the lower end of the embedded region is shallower than a lower end of the contact region.

7. The semiconductor device according to claim 5, further comprising a contact region of a second conductivity type provided in the front surface of the semiconductor substrate, wherein
the lower end of the embedded region is shallower than a lower end of the contact region.

8. The semiconductor device according to claim 4, further comprising a contact region of a second conductivity type provided in the front surface of the semiconductor substrate, wherein
the lower end of the embedded region is deeper than a lower end of the contact region.

9. The semiconductor device according to claim 5, further comprising a contact region of a second conductivity type provided in the front surface of the semiconductor substrate, wherein
the lower end of the embedded region is deeper than a lower end of the contact region.

10. The semiconductor device according to claim 1, wherein, in a trench array direction, one side wall of side walls of the upper region is located on a first mesa portion that is in direct contact with the dummy trench portion, and an other side wall is located on a second mesa portion that is in direct contact with the dummy trench portion on a side opposite to the first mesa portion.

11. The semiconductor device according to claim 1, comprising a plurality of dummy trench portions adjacently arrayed, wherein
the upper region is provided extending across the plurality of dummy trench portions in a trench array direction.

12. The semiconductor device according to claim 1, comprising a transistor portion provided with the gate trench portion and the dummy trench portion, and a diode portion provided with the dummy trench portion.

13. The semiconductor device according to claim 12, wherein
a plurality of dummy trench portions are adjacently arrayed in the diode portion, and
the upper region is provided extending from a dummy trench portion of the plurality of dummy trench portions that is adjacent to the gate trench portion to a dummy trench portion on an opposite side, in a trench array direction.

14. The semiconductor device according to claim 12, wherein a plurality of gate trench portions and a plurality of dummy trench portions are alternately arrayed in the transistor portion.

15. The semiconductor device according to claim 13, wherein a plurality of gate trench portions and a plurality of dummy trench portions are alternately arrayed in the transistor portion.

16. The semiconductor device according to claim 1, wherein a lower end of the upper region is provided below a front surface of the semiconductor substrate.

17. The semiconductor device according to claim 16, further comprising a contact region of a second conductivity type provided in the front surface of the semiconductor substrate, wherein
the lower end of the upper region is shallower than a lower end of the contact region.

18. The semiconductor device according to claim 1, wherein each of the upper region and the embedded region has a plug containing tungsten and a barrier metal containing titanium.

19. The semiconductor device according to claim 1, wherein
the front surface metal layer further has an emitter electrode provided on the upper region,
each of the emitter electrode and the upper region has a conductive material containing aluminum, and
the embedded region has a plug containing tungsten and a barrier metal containing titanium.

20. The semiconductor device according to claim 19, wherein the upper region has a tapered shape with inclined side walls.
